(19) United States
(12) Patent Application Publication
(10) Pub. No.: US 2025/0167054 A1
(43) Pub. Date: May 22, 2025

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventor: DUCKGYU KIM, Suwon-si (KR)

(21) Appl. No.: 18/675,860

(22) Filed: May 28, 2024

(30) Foreign Application Priority Data
Nov. 20, 2023 (KR) 10-2023-0161481

(51) Int. Cl. H01L 21/66; H01L 23/544

(52) U.S. Cl. CPC H01L 22/32; H01L 23/544; H01L 2223/5446

(57) ABSTRACT

Disclosed are semiconductor chips and semiconductor packages including the same. The semiconductor chip comprises a substrate that includes a device region and an edge region, a conductive pad on the device region of the substrate, a residual test pattern on the edge region of the substrate, and a redistribution layer on the substrate and covering the conductive pad. The redistribution layer includes a first dielectric layer and a second dielectric layer. The residual test pattern includes a pattern cut part that has a lateral surface aligned with that of the substrate, and a pattern edge part between the pattern cut part and the conductive pad. The first dielectric layer entirely covers the pattern edge part and partially covers the pattern cut part. There is a step difference between sidewalls of the first and second dielectric layers such that the second dielectric layer does not cover the residual test pattern.

### CROSS-REFERENCE TO RELATED APPLICATION

This U.S. nonprovisional application claims priority under 35 U.S.C § 119 to Korean Patent Application No. 10-2023-0161481 filed on Nov. 20, 2023 in the Korean Intellectual Property Office, the disclosure of which is hereby incorporated by reference in its entirety.

### BACKGROUND

The present inventive concepts relate to a semiconductor chip and a semiconductor package including the same, and more particularly, to a semiconductor chip comprising a residual test pattern and a semiconductor package including the same.

In general, a wafer on which semiconductor devices are formed is divided into a chip region on which a plurality of cells are formed and a scribe lane which distinguishes chips from each other. A plurality of semiconductor devices, such as transistors, resistors, and capacitors, are formed on the chip regions and are not formed on the scribe lane. The wafer is sawed along the scribe lane to complete or separate each of the semiconductor devices (or semiconductor chips). The scribe lane may be provided thereon with an alignment key for an exposure process and/or with a test pattern for monitoring electrical properties and defective patterns of the semiconductor devices formed on the chip regions to inspect whether a process is normally performed. The test process may measure electrical properties of semiconductor devices to determine whether each process is normally performed and to ascertain characteristics of unit device such as transistor, metal wire resistance, via resistance, and the like.

### SUMMARY

Some embodiments of the present inventive concepts provide a semiconductor chip with improved durability.

Some embodiments of the present inventive concepts provide a semiconductor package with improved durability.

Objects of the present inventive concepts are not limited to those mentioned above, and other objects which have not been mentioned above will be clearly understood to those skilled in the art from the following description.

According to some embodiments of the present inventive concepts, a semiconductor chip may comprise: a substrate that includes a device region and an edge region; a conductive pad on the device region of the substrate; at least one residual test pattern on the edge region of the substrate; and a redistribution layer on the substrate and covering the conductive pad. The redistribution layer may include a first dielectric layer and a second dielectric layer. The at least one residual test pattern may include: a pattern cut part that has a lateral surface aligned with a lateral surface of the substrate; and a pattern edge part between the pattern cut part and the conductive pad. The first dielectric layer may entirely cover the pattern edge part and partially cover the pattern cut part. There may be a step difference between a sidewall of the first dielectric layer and a sidewall of the second dielectric layer such that the second dielectric layer does not cover the at least one residual test pattern.

According to some embodiments of the present inventive concepts, a semiconductor chip may comprise: a substrate that includes a device region and an edge region; a conductive pad on the device region of the substrate; at least one residual test pattern on the edge region of the substrate; a passivation layer that covers the substrate, the conductive pad, and the at least one residual test pattern; a connection via that penetrates the substrate and connects with the conductive pad; a redistribution layer on the passivation layer and including a first dielectric layer and a second dielectric layer; a redistribution pattern between the first dielectric layer and the second dielectric layer; a conductive bump on the second dielectric layer and connected to the redistribution pattern; and a first external connection member connected to the conductive bump. The at least one residual test pattern may include: a pattern cut part that has a lateral surface aligned with a lateral surface of the substrate; and a pattern edge part between the pattern cut part and the conductive pad. The first dielectric layer may entirely cover the pattern edge part and partially cover the pattern cut part. There may be a step difference between a sidewall of the first dielectric layer and a sidewall of the second dielectric layer such that the second dielectric layer does not cover the at least one residual test pattern.

According to some embodiments of the present inventive concepts, a semiconductor package may comprise: a package substrate; a semiconductor chip on the package substrate; and a mold layer that covers the semiconductor chip and a top surface of the package substrate. The semiconductor chip may include: a chip substrate that includes a device region and an edge region; a conductive pad on the device region and below the chip substrate; at least one residual test pattern on the edge region and below the chip substrate; a redistribution layer on a bottom surface of the chip substrate, the redistribution layer including a first dielectric layer and a second dielectric layer; a redistribution pattern between the first dielectric layer and the second dielectric layer; and a conductive bump below the second dielectric layer and connected to the redistribution pattern. The at least one residual test pattern may include: a pattern cut part that has a lateral surface aligned with a lateral surface of the chip substrate; and a pattern edge part between the pattern cut part and the conductive pad. The first dielectric layer may entirely cover the pattern edge part and partially cover the pattern cut part. There may be a step difference between a sidewall of the first dielectric layer and a sidewall of the second dielectric layer such that the second dielectric layer does not cover the at least one residual test pattern.

### BRIEF DESCRIPTION OF DRAWINGS

FIG. 1A illustrates a plan view showing a semiconductor chip according to some embodiments of the present inventive concepts.

FIG. 1B illustrates an enlarged view showing section P1 of FIG. 1A.

FIG. 2A illustrates a cross-sectional view taken along line A-A′ of FIG. 1B according to some embodiments of the present inventive concepts.

FIG. 2B illustrates a cross-sectional view taken along line B-B′ of FIG. 1B according to some embodiments of the present inventive concepts.

FIG. 2C illustrates a cross-sectional view taken along line C-C′ of FIG. 1B according to some embodiments of the present inventive concepts.

FIG. 3 illustrates a plan view showing a wafer according to some embodiments of the present inventive concepts.

FIGS. 4A to 4G illustrate cross-sectional views showing a method of fabricating a semiconductor chip depicted in FIG. 2A according to some embodiments of the present inventive concepts.

FIG. 5 illustrates an enlarged plan view of section P2 depicted in FIG. 3, showing a method of fabricating a semiconductor chip of FIG. 1B according to some embodiments of the present inventive concepts.

FIG. 6A illustrates a cross-sectional view taken along line D-D′ of FIG. 5 according to some embodiments of the present inventive concepts.

FIG. 6B illustrates a cross-sectional view taken along line E-E′ of FIG. 5 according to some embodiments of the present inventive concepts.

FIG. 6C illustrates a cross-sectional view taken along line F-F′ of FIG. 5 according to some embodiments of the present inventive concepts.

FIG. 7 illustrates a cross-sectional view showing a method of fabricating a semiconductor package depicted in FIG. 2A according to some embodiments of the present inventive concepts.

FIG. 8 illustrates a cross-sectional view showing a semiconductor package according to some embodiments of the present inventive concepts.

### DETAILED DESCRIPTION OF EMBODIMENTS

Some embodiments of the present inventive concepts will now be described in detail with reference to the accompanying drawings to aid in clearly explaining the present inventive concepts.

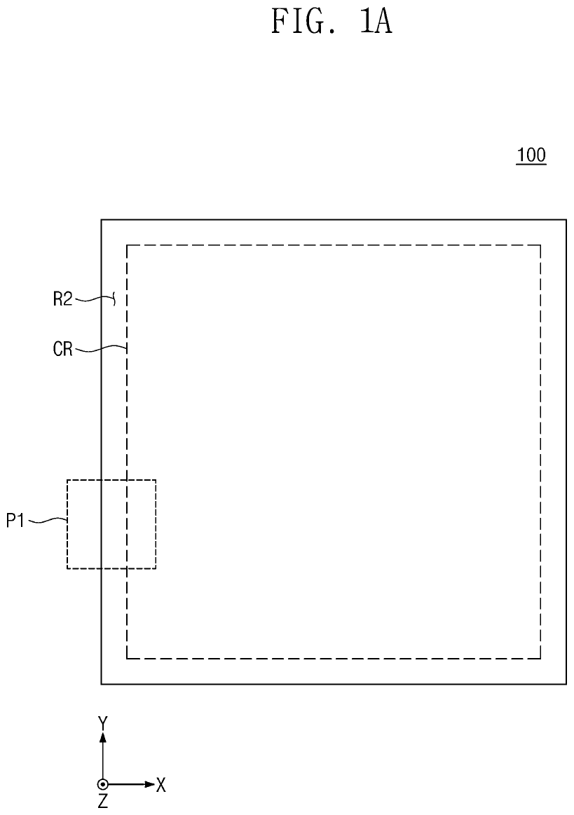

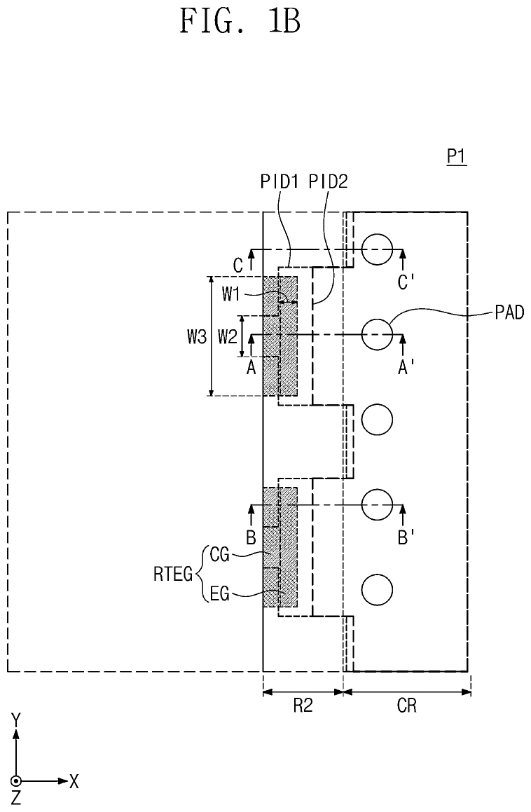

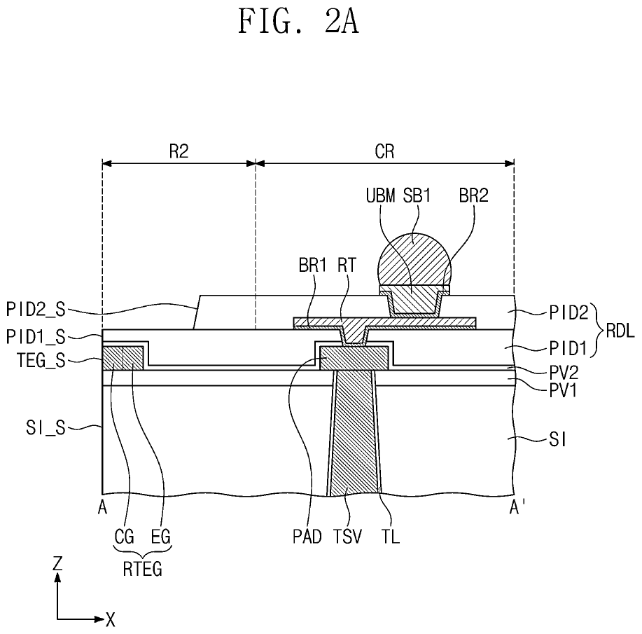

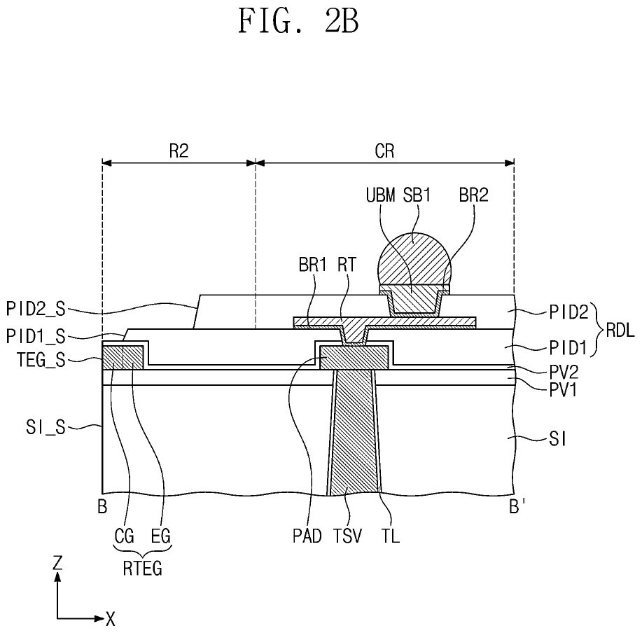

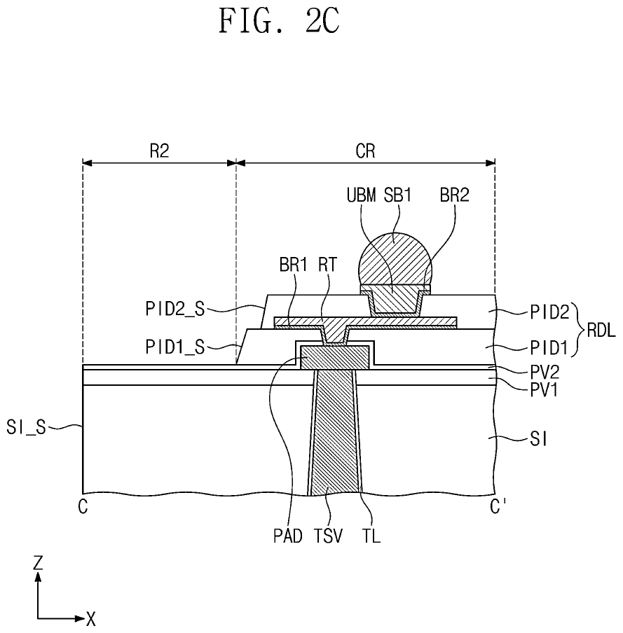

FIG. 1A illustrates a plan view showing a semiconductor chip according to some embodiments of the present inventive concepts. FIG. 1B illustrates an enlarged view showing section P1 of FIG. 1A. FIG. 2A illustrates a cross-sectional view taken along line A-A′ of FIG. 1B according to some embodiments of the present inventive concepts. FIG. 2B illustrates a cross-sectional view taken along line B-B′ of FIG. 1B according to some embodiments of the present inventive concepts. FIG. 2C illustrates a cross-sectional view taken along line C-C′ of FIG. 1B according to some embodiments of the present inventive concepts.

Referring to FIGS. 1A, 1B, 2A, and 2B, a semiconductor chip 100 according to the present embodiment may include a substrate SI. The substrate SI may include, for example, a semiconductor material. The substrate SI may be a monocrystalline silicon substrate. The substrate Si may include a device region CR and an edge region R2 that surrounds the device region CR. Although not shown, integrated circuits including transistors may be disposed on the substrate SI.

On the device region CR of the substrate SI, a plurality of conductive pads PAD may be disposed on the substrate SI. The conductive pads PAD may include metal, such as gold, nickel, aluminum, or tungsten.

On the edge region R2 of the substrate SI, a residual test pattern RTEG may be disposed on the substrate SI. The substrate SI may be provided thereon with a plurality of residual test patterns RTEG along the edge region R2. The residual test patterns RTEG may be disposed spaced apart in a first direction X from the conductive pads PAD. The residual test patterns RTEG may be disposed spaced apart from each other in a second direction Y. The residual test patterns RTEG may be formed of the same material as that of the conductive pad PAD. Each residual test pattern RTEG may include a pattern cut part CG and a pattern edge part EG. A lateral surface TEG_S of the pattern cut part CG may be aligned with a lateral surface SI_S of the substrate SI. The pattern edge part EG may be positioned between the pattern cut part CG and the conductive pad PAD.

A connection via TSV may be disposed to penetrate the substrate SI. The connection via TSV may be connected to the conductive pad PAD. The connection via TSV may include metal, such as copper, aluminum, or tungsten. A via dielectric layer TL may be interposed between the substrate SI and the connection via TSV. The via dielectric layer TL may have a single-layered or multi-layered structure including at least one selected from silicon oxide, silicon nitride, and silicon oxynitride. The via dielectric layer TL may include an air gap.

A first passivation layer PV1 may be disposed on the substrate SI. The connection via TSV and the via dielectric layer TL may penetrate the first passivation layer PV1. The conductive pads PAD and the residual test patterns RTEG may be disposed on the first passivation layer PV1. The first passivation layer PV1 may be provided thereon with a second passivation layer PV2 that covers the first passivation layer PV1, the conductive pads PAD, and the residual test patterns RTEG. Each of the first and second passivation layers PV1 and PV2 may have a single-layered or multi-layered structure including at least one selected from silicon oxide, silicon nitride, and silicon carbonitride.

A redistribution layer RDL may be disposed on the substrate SI. The redistribution layer RDL may include a first dielectric layer PID1 and a second dielectric layer PID2 that are sequentially stacked. The present inventive concepts, however, are not limited thereto, and the redistribution layer RDL may be formed of three or more stacked dielectric layers. Each of the first and second dielectric layers PID1 and PID2 may include, for example, a photo-imageable dielectric (PID) layer. The first dielectric layer PID1 may be disposed on the second passivation layer PV2. The first dielectric layer PID1 may cover the device region CR and a portion of the edge region R2. The first dielectric layer PID1 may cover the second passivation layer PV2 and a portion of the substrate SI. The first dielectric layer PID1 may be provided thereon with the second dielectric layer PID2 that covers a portion of the first dielectric layer PID1. The second dielectric layer PID2 may cover the device region CR.

A redistribution pattern RT may be disposed between the first dielectric layer PID1 and the second dielectric layer PID2. The redistribution pattern RT may be in contact with the conductive pad PAD and may be connected through the conductive pad PAD to the connection via TSV. The redistribution pattern RT may include metal, such as copper, aluminum, gold, nickel, or titanium. A first barrier layer BR1 may be interposed between the redistribution pattern RT and the first dielectric layer PID1.

The second dielectric layer PID2 may be provided thereon with a conductive bump UBM connected to the redistribution pattern RT. The conductive bump UBM may be connected through the redistribution pattern RT to the conductive pad PAD. The conductive bump UBM may include metal, such as copper. A second barrier layer BR2 may be interposed between the conductive bump UBM and the second dielectric layer PID2. Each of the first and second barrier layers BR1 and BR2 may include, for example, titanium, tantalum, titanium nitride, tantalum, or tungsten nitride.

A first external connection member SB1 may be bonded to the conductive bump UBM. The first external connection member SB1 may include metal, such as at least one selected from copper, nickel, tin, lead, and silver.

Referring to FIG. 1B, neither the first dielectric layer PID1 nor the second dielectric layer PID2 may cover a space between the residual test patterns RTEG. The first dielectric layer PID1 may entirely cover the pattern edge part EG. However, the first dielectric layer PID1 may partially cover the pattern cut part CG. For example, the first dielectric layer PID1 may cover the pattern edge part EG by a first width W1 in the first direction X, and the first width W1 may range from about 5 μm to about 10 μm. The first dielectric layer PID1 may cover the pattern cut part CG by a second width W2 in the second direction Y that intersects (i.e., is transverse to) the first direction X, and the second width W2 may range from about 10 μm to about 20 μm. For example, the second width W2 may be less than a third width W3 of the residual test pattern RTEG.

On a section where the test pattern TEG is absent, the first dielectric layer PID1 may not cover the edge region R2. The first dielectric layer PID1 may cover the device region CR. A sidewall PID1_S of the first dielectric layer PID1 may be inclined and adjacent to the pattern cut part CG.

Referring to FIGS. 2A to 2C, there is a a step difference between the sidewall PID1_S of the first dielectric layer PID1 and a sidewall PID2_S of the second dielectric layer PID2, as illustrated. In other words, when viewed in cross section, as shown in FIGS. 2A-2C, the sidewall PID1_S of the first dielectric layer PID1 and the sidewall PID2_S of the second dielectric layer PID2 are off-set relative to each other along the X direction (i.e., they form a step configuration relative to each other, as illustrated).

As shown in FIG. 2A, the pattern cut part CG may have a top surface covered with the first dielectric layer PID1 and a lateral surface TEG_S not covered with the first dielectric layer PID1. As the top surface of the pattern cut part CG is covered with the first dielectric layer PID1, the pattern cut part CG and the substrate SI may be prevented from being delaminated therebetween possibly occurring after sawing of the semiconductor chip 100. In addition, the residual test patterns RTEG may be protected and prevented from being torn or removed due to external force. Therefore, the semiconductor chip 100 may increase in durability.

As shown in FIG. 2A, the sidewall PID2_S of the second dielectric layer PID2 may be inclined. However, the sidewall PID1_S of the first dielectric layer PID1 may be perpendicular on an edge of the top surface of the pattern cut part CG. The second dielectric layer PID2 may not cover the residual test pattern RTEG. The sidewall PID2_S of the second dielectric layer PID2 may be positioned between the pattern edge part EG and the conductive pad PAD.

As shown in FIG. 2B, the sidewall PID2_S of the second dielectric layer PID2 may be inclined, and the sidewall PID1_S of the first dielectric layer PID1 may be inclined and adjacent to the pattern cut part CG. In this case, the first dielectric layer PID1 may not cover the pattern cut part CG. The second dielectric layer PID2 may not cover the residual test pattern RTEG. On the edge region R2, the sidewall PID2_S of the second dielectric layer PID2 may be positioned between the pattern edge part EG and the conductive pad PAD.

As shown in FIG. 2C, on a section where the residual test pattern RTEG is absent, any of the first dielectric layer PID1 and the second dielectric layer PID2 may not cover the edge region R2 and may cover the device region CR. In this case, the sidewall PID1_S of the first dielectric layer PID1 may be inclined, and likewise the sidewall PID2_S of the second dielectric layer PID2 may be inclined.

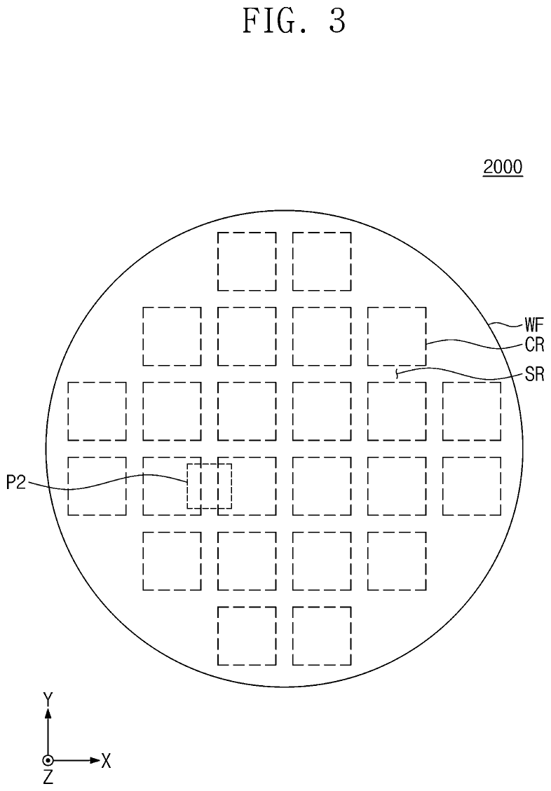

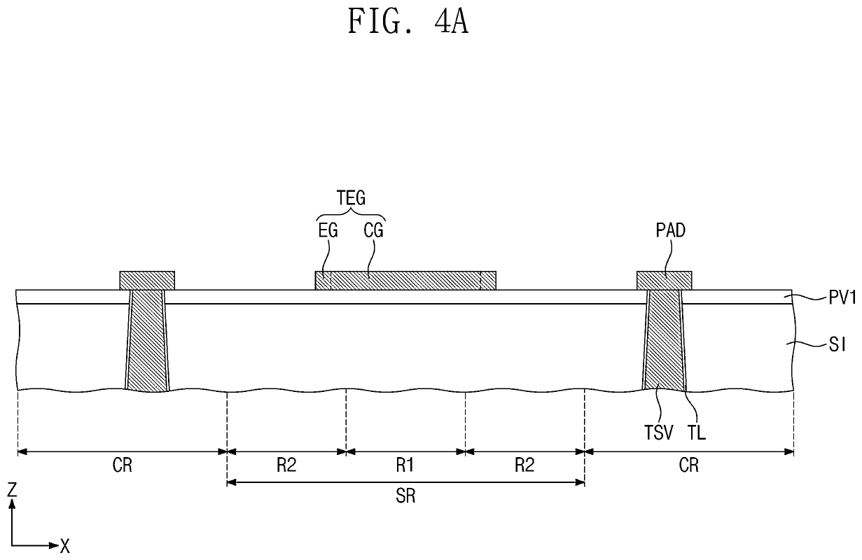

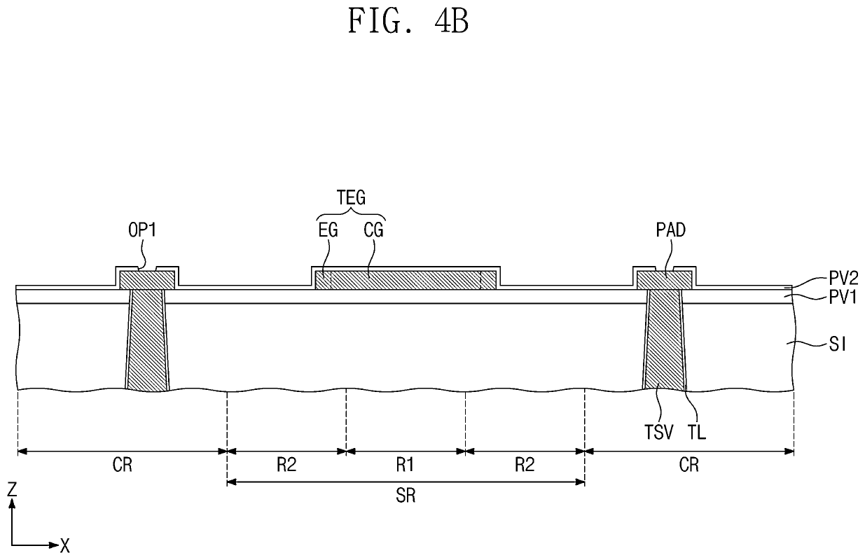

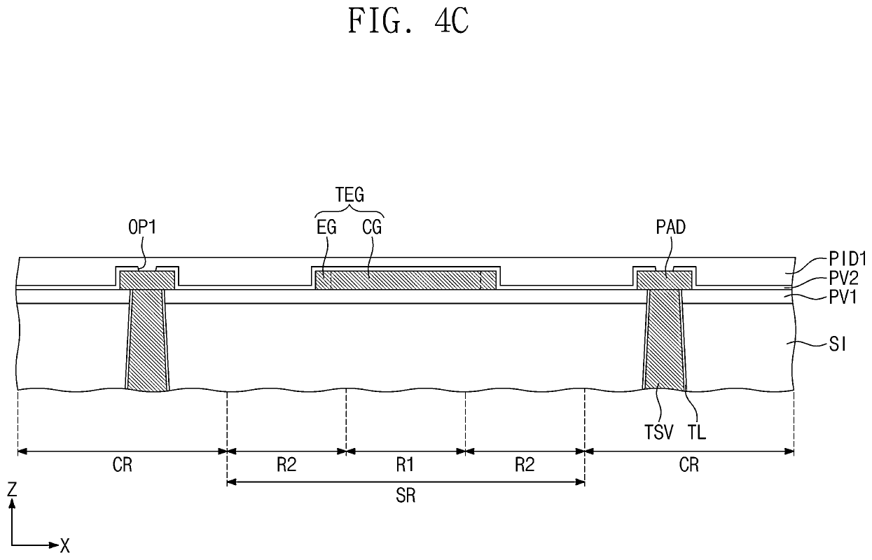

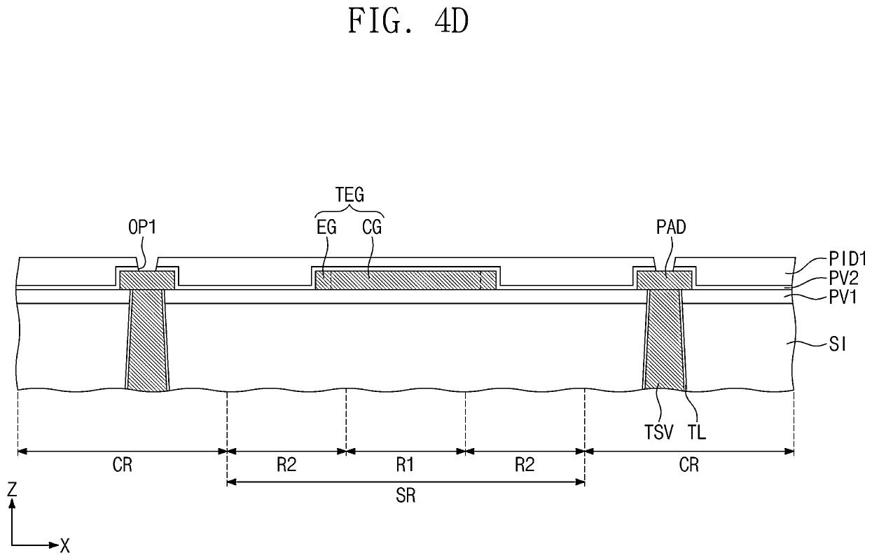

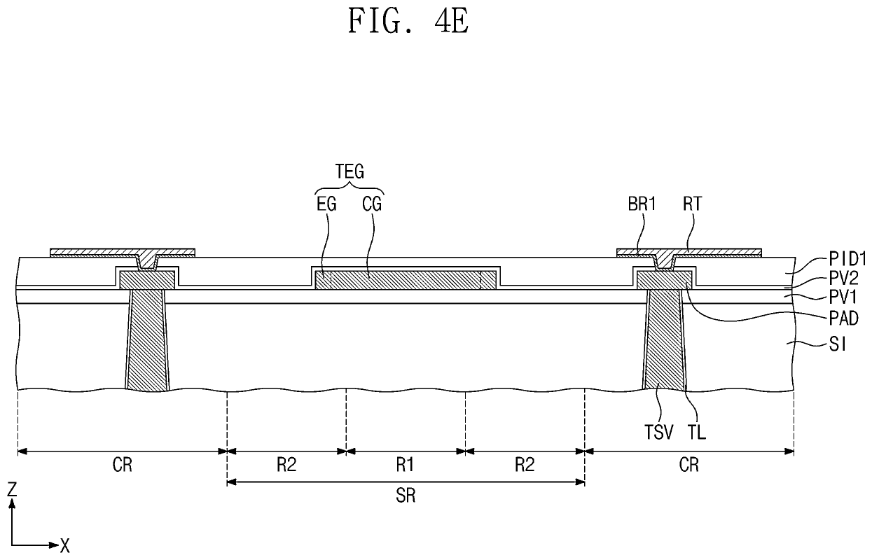

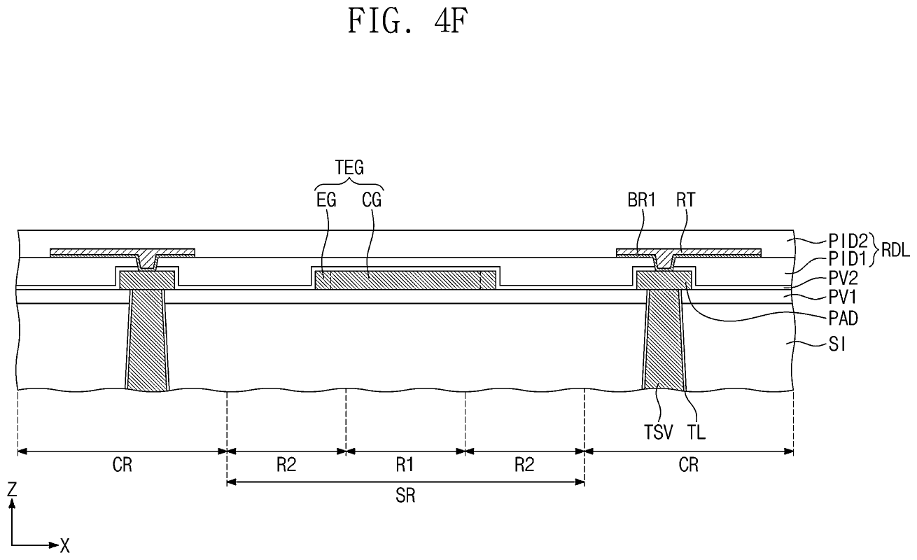

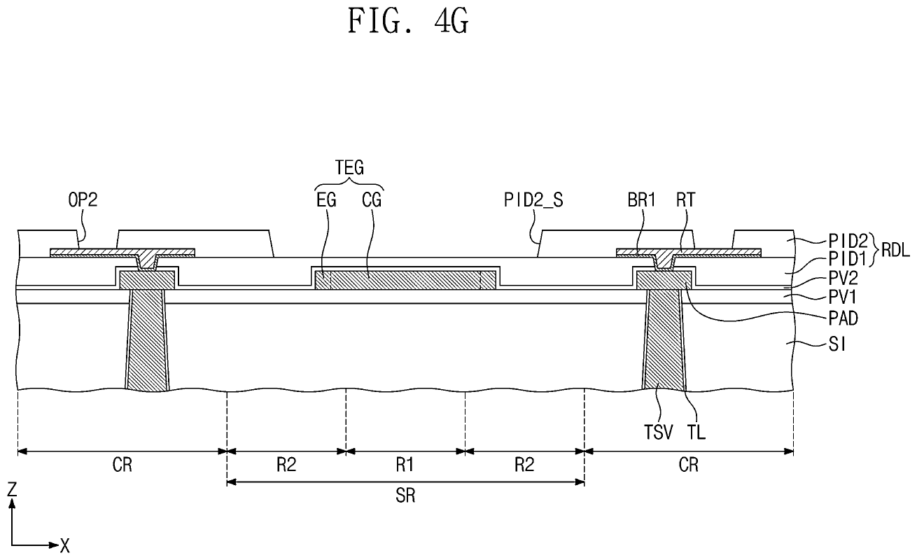

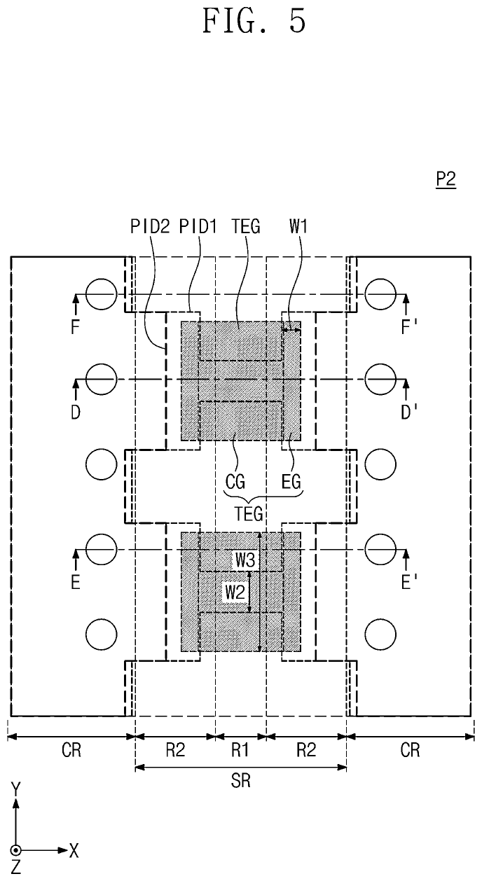

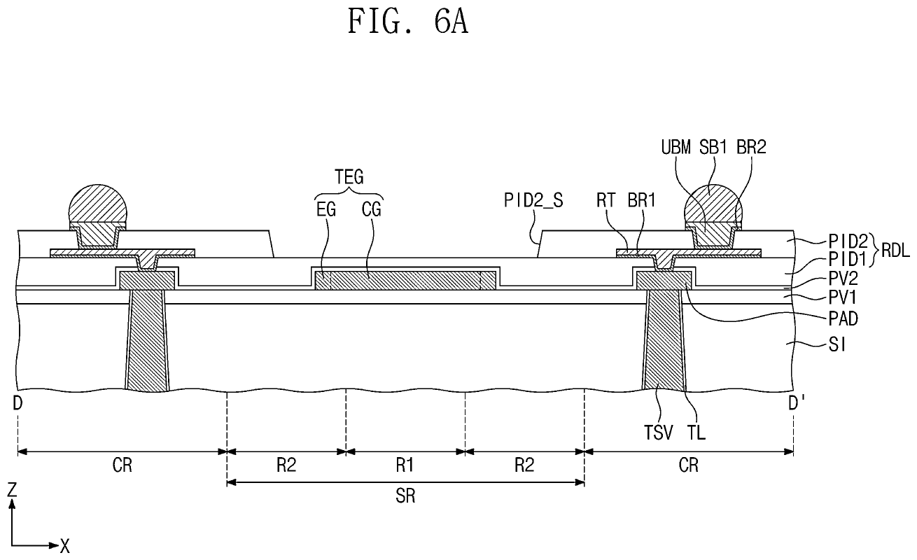

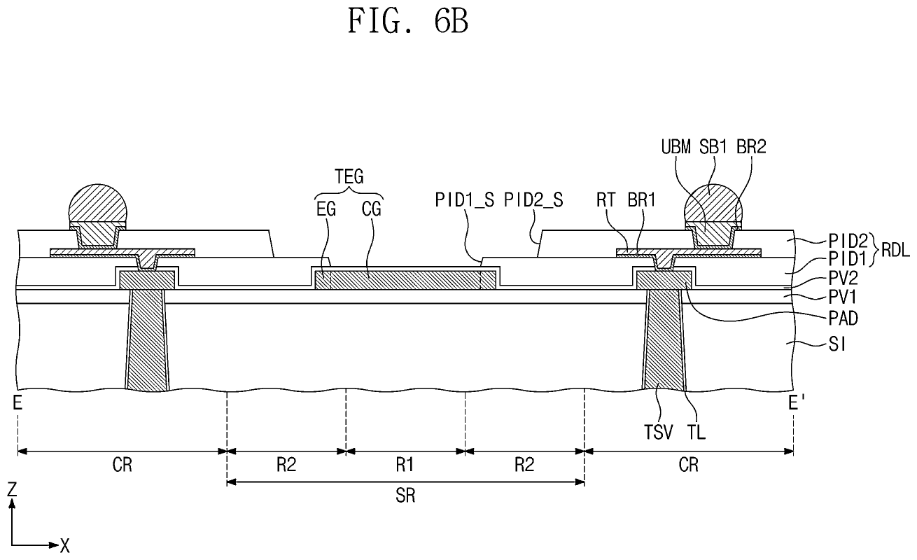

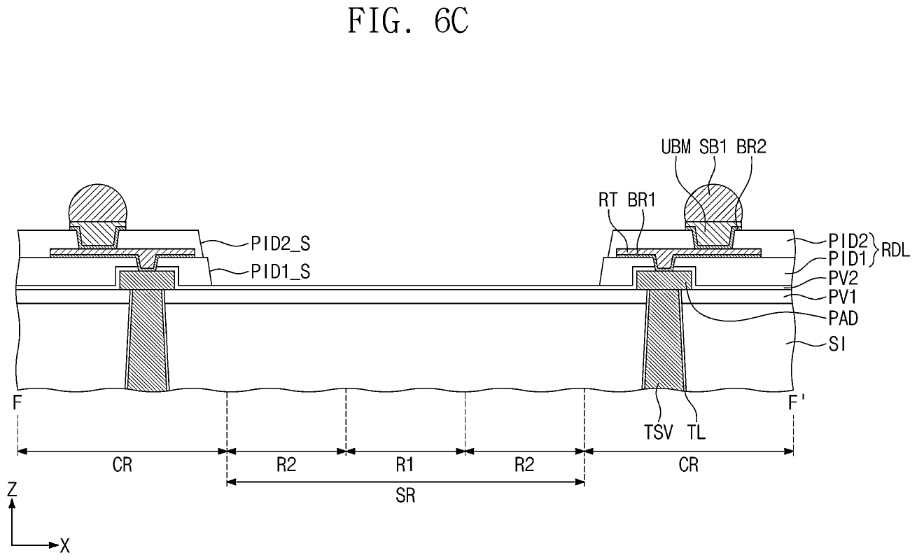

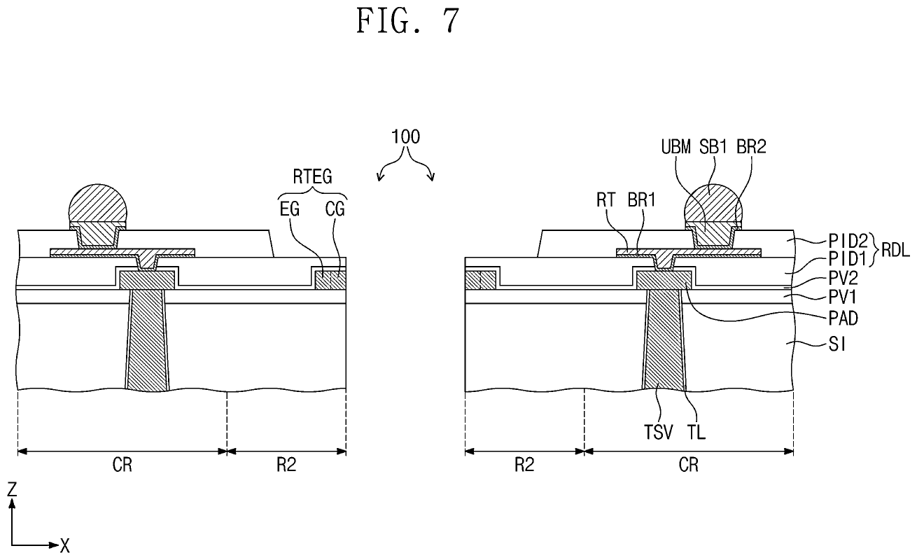

FIG. 3 illustrates a plan view showing a wafer according to some embodiments of the present inventive concepts. FIGS. 4A to 4G illustrate cross-sectional views showing a method of fabricating a semiconductor chip depicted in FIG. 2A according to some embodiments of the present inventive concepts. FIG. 5 illustrates a plan view showing a method of fabricating a semiconductor chip depicted in FIG. 1B. FIG. 5 illustrates an enlarged view showing section P2 of FIG. 3. FIG. 6A illustrates a cross-sectional view taken along line D-D′ of FIG. 5 according to some embodiments of the present inventive concepts. FIG. 6B illustrates a cross-sectional view taken along line E-E′ of FIG. 5 according to some embodiments of the present inventive concepts. FIG. 6C illustrates a cross-sectional view taken along line F-F′ of FIG. 5 according to some embodiments of the present inventive concepts. FIG. 7 illustrates a cross-sectional view showing a method of fabricating a semiconductor package depicted in FIG. 2A according to some embodiments of the present inventive concepts.

Referring to FIG. 3, a plurality of device regions CR may be arranged on a wafer WF. Each of the device regions CR may correspond to the device region CR of the semiconductor chip 100 discussed with reference to FIGS. 1A to 2C. A scribe lane region SR may be disposed between the device regions CR. The scribe lane region SR may include a cut region R1 and an edge region R2.

Referring to FIGS. 3 and 5, a plurality of test patterns TEG may be disposed on the scribe lane region SR. The test patterns TEG may be disposed spaced apart in a first direction X from conductive pads PAD. The test patterns TEG may be disposed spaced apart from each other in a second direction Y. The test pattern TEG may include a pattern cut part CG positioned on a central portion and a pattern edge part EG positioned on an edge portion in the first direction X from the pattern cut part CG. The cut region R1 may be positioned in the pattern cut part CG. The wafer WF may correspond to the substrate SI of FIGS. 4A to 4H. Although not shown, the scribe lane region SR may be provided thereon with guard ring structures, chipping dam structures, and alignment keys.

Referring to FIG. 4A, a substrate SI may be prepared. An ordinary procedure may be employed to form a connection via TSV and a via dielectric layer TL on a device region CR of the substrate SI. The substrate SI may be back-grinded, and then a first passivation layer PV1 may be formed on the substrate SI. Although not shown, integrated circuits including transistors may be formed on the substrate SI.

Plating and etching processes may be performed to conductive pads PAD and test patterns TEG on the first passivation layer PV1. The conductive pads PAD may be connected corresponding connection vias TSV. The test patterns TEG may be formed on a scribe lane region SR, while being spaced apart from the conductive pads PAD. As shown in FIG. 5, the test patterns TEG may be formed spaced apart from each other. The test patterns TEG may each include a pattern cut part CG and a pattern edge part EG.

Referring to FIG. 4B, a second passivation layer PV2 may be formed to cover the first passivation layer PV1, the conductive pads PAD, and the test patterns TEG. The second passivation layer PV2 may be etched to form a first opening OP1 that exposes the conductive pad PAD.

Referring to FIG. 4C, a first dielectric layer PID1 may be formed on the second passivation layer PV2. The first dielectric layer PID1 may be formed to cover the conductive pads PAD and the test patterns TEG. The first dielectric layer PID1 may be formed of a photo-imageable dielectric layer. The first dielectric layer PID1 may be formed through coating and baking processes.

Referring to FIGS. 4D, 5, 6B, and 6C, exposure and development processes may be performed to form in the first dielectric layer PID1 a first opening OP1 that exposes the conductive pad PAD. A planar shape of the first dielectric layer PID1 may be formed as shown in FIG. 5. For example, the first dielectric layer PID1 may cover an entirety of the pattern edge part EG. The first dielectric layer PID1 may cover the pattern edge part EG by a first width W1 in the first direction X, and the first width W1 may range from about 5 μm to about 10 μm. The first dielectric layer PID1 may partially cover the pattern cut part CG. The first dielectric layer PID1 may run in the first direction X across the pattern cut part CG. The first dielectric layer PID1 may cover the pattern cut part CG by a second width W2 in the second direction Y that intersects (i.e., is transverse to) the first direction X, and the second width W2 may range from about 10 μm to about 20 μm. For example, the second width W2 may be less than a third width W3 of the test pattern TEG.

On a section where the test pattern TEG is absent, the first dielectric layer PID1 may not cover any of a cut region R1 and an edge region R2. The first dielectric layer PID1 may cover the device region CR. A sidewall PID1_S of the first dielectric layer PID1 may be inclined and adjacent to the pattern cut part CG.

Referring to FIG. 4E, a deposition process may be performed to from a first barrier layer BR1 in the first opening OP1 and a front surface of the first dielectric layer PID1. A mask pattern (not shown) may be formed on the first dielectric layer PID1, thereby limiting a shape of a redistribution pattern RT which will be discussed below. The first barrier layer BR1 may be used as a seed layer to perform a plating process to form a redistribution pattern RT on the first barrier layer BR1. The mask pattern (not shown) may be removed, and the first barrier layer BR1 exposed on a side of the redistribution pattern RT may be removed to expose the first dielectric layer PID1.

Referring to FIG. 4F, a second dielectric layer PID2 may be formed to cover the redistribution pattern RT and the first dielectric layer PID1. The second dielectric layer PID2 may be formed of a photo-imageable dielectric layer. The second dielectric layer PID2 may be formed through coating and baking processes.

Referring to FIGS. 4G, 5, 6B, and 6C, exposure and development processes may be performed to form in the second dielectric layer PID2 a second opening OP2 that exposes a portion of the redistribution pattern RT. In this step, a portion of the second dielectric layer PID2 on the scribe lane region SR may be removed to expose the test pattern TEG. On a section where the test pattern TEG is absent, the second dielectric layer PID2 may not cover any of the cut region R1 and the edge region R2. The second dielectric layer PID2 may cover the device region CR. A sidewall PID2_S of the second dielectric layer PID2 may be formed inclined, and on the edge region R2, the sidewall PID2_S of the second dielectric layer PID2 may be positioned between the conductive pad PAD and the pattern edge part EG. The first dielectric layer PID1 and the second dielectric layer PID2 may constitute a redistribution layer RDL.

Subsequently, although not shown, the test patterns TEG may be provided with test signals to perform a test process. The test process may measure electrical properties of a semiconductor chip to determine whether each process is normally performed and to ascertain characteristics of unit device such as a transistor, metal wire resistance, via resistance, and the like.

Referring to FIGS. 6A to 6C, a deposition process may be performed to form a second barrier layer BR2 in the second opening OP2 and a front surface of the second dielectric layer PID2. A mask pattern (not shown) may be formed on the second dielectric layer PID2 to limit shapes of conductive bumps UBM which will be discussed below. The second barrier layer BR2 may be used as a seed layer to perform a plating process to form conductive bumps UBM and first external connection members SB1 on the second barrier layer BR2. A reflow process may be performed such that the first external connection members SB1 are formed to have their rounded shapes. The mask pattern (not shown) may be removed, and the second barrier layer BR2 exposed on a side of the conductive bumps UBM may be removed to expose the second dielectric layer PID2.

Referring to FIG. 7, a blade may be used to perform a sawing process to remove the cut region R1 and to form a plurality of semiconductor chips 100 separated from each other. This step may remove the substrate SI, the first and second passivation layers PV1 and PV2, the pattern cut part CG, and the first dielectric layer PID1 on the cut region R1. A portion of the pattern cut part CG of the test pattern TEG may be cut off to form residual test patterns RTEG. The residual test pattern RTEG may include the cut-off pattern cut part CG and the pattern edge part EG. It may thus be possible to fabricate the semiconductor chip 100 which is discussed with reference to FIGS. 1A to 2C.

In the present inventive concepts, the residual test patterns RTEG in the cut region R1 may be partially covered with the first dielectric layer PID1, and thus a blade may be prevented from being damaged by the first dielectric layer PID1, which may result in an increase in lifespan of the blade and an improvement in sawing quality. In addition, after sawing of the semiconductor chips 100, a delamination may be prevented between the residual test patterns RTEG and the substrate SI. Moreover, the residual test patterns RTEG may be protected by the first dielectric layer PID1 and may thus be prevented from being torn or removed due to external force. Thus, the semiconductor chips 100 may improve in durability. A section other than the cut region R1 on the scribe lane region SR after the sawing process may become an edge region R2 of the semiconductor chip 100.

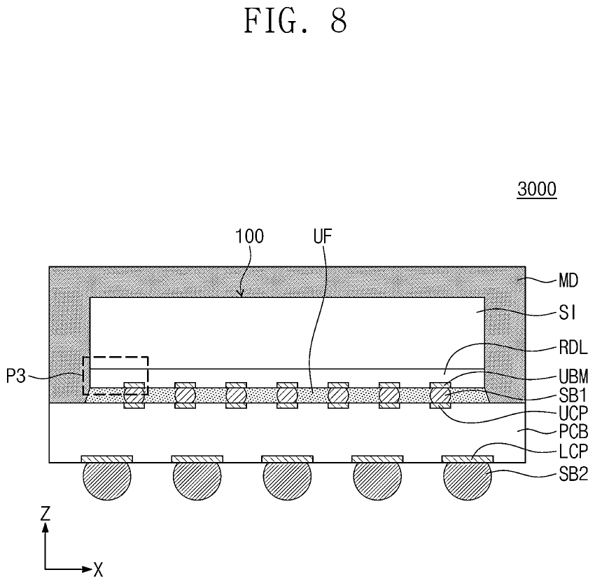

FIG. 8 illustrates a cross-sectional view showing a semiconductor package according to some embodiments of the present inventive concepts.

Referring to FIG. 8, in a semiconductor package 3000 according to the present embodiment, a semiconductor chip 100 may be disposed on a package substrate PCB. The package substrate PCB may be, for example, a double-sided or multi-layered printed circuit board. The package substrate PCB may include upper conductive pads UCP on a top surface thereof and lower conductive pads LCP on a bottom surface thereof. The semiconductor chip 100 may be the same as or similar to the semiconductor chip 100 discussed with reference to FIGS. 1A to 2C.

The semiconductor chip 100 may include a redistribution layer RDL and a substrate SI disposed on the redistribution layer RDL. Conductive bumps UBM may be disposed on a bottom surface of the redistribution layer RDL. First external connection members SB1 may be disposed to connect the upper conductive pads UCP to the conductive bumps UBM. For example, the semiconductor chip 100 may be connected through the first external connection members SB1 to the package substrate PCB. An underfill UF may be provided between the package substrate PCB and the semiconductor chip 100. The underfill UF may be formed through dispensing and curing processes. The underfill UF may include an epoxy resin, and may protect the first external connection members SB1.

Second external connection members SB2 may be bonded to the lower conductive pads LCP of the package substrate PCB. The first and second external connection members SB1 and SB2 may include metal, such as at least one selected from copper, nickel, tin, lead, and silver. A mold layer MD may cover the semiconductor chip 100 and the top surface of the package substrate PCB. The mold layer MD may include a dielectric resin, such as an epoxy molding compound (EMC). The mold layer MD may further include fillers, and the fillers may be dispersed in the dielectric resin. The fillers may include, for example, silicon oxide (SiO₂).

A portion obtained by magnifying section P3 of FIG. 8 may be similar to that obtained by overturning FIGS. 2A to 2C. Referring to FIGS. 2A to 2C, as the residual test patterns RTEG are covered with the first dielectric layer PID1, a delamination may be prevented between the residual test patterns RTEG and the substrate SI, and the residual test patterns RTEG may be prevented from being torn and removed due to external force. The semiconductor package 3000 may thus have an improved durability. Other configurations may be identical or similar to those discussed with reference to FIGS. 1A to 2C.

In a semiconductor chip and a semiconductor package including the same according to some embodiments of the present inventive concepts, a cut part of a residual test pattern may be coated with a dielectric layer, and thus the residual test pattern may be protected and prevented from being damaged due to external force. In addition, the residual test pattern may be prevented from delamination possibly occurring after the semiconductor chip is diced. Accordingly, the semiconductor chip and the semiconductor package may increase in durability.

Although some embodiments of inventive concepts have been discussed with reference to accompanying figures, it will be understood that various changes in form and details may be made therein without departing from the scope of inventive concepts. It will be apparent to those skilled in the art that various substitution, modifications, and changes may be thereto without departing from the scope of the present inventive concepts.

What is claimed is:

1. A semiconductor chip, comprising:
a substrate comprising a device region and an edge region;
a conductive pad on the device region of the substrate;
at least one residual test pattern on the edge region of the substrate; and
a redistribution layer on the substrate and covering the conductive pad,
wherein the redistribution layer comprises a first dielectric layer and a second dielectric layer,
wherein the at least one residual test pattern comprises:
a pattern cut part that has a lateral surface aligned with a lateral surface of the substrate; and
a pattern edge part between the pattern cut part and the conductive pad,
wherein the first dielectric layer entirely covers the pattern edge part and partially covers the pattern cut part, and
wherein there is a step difference between a sidewall of the first dielectric layer and a sidewall of the second dielectric layer such that the second dielectric layer does not cover the at least one residual test pattern.

2. The semiconductor chip of claim 1, further comprising a redistribution pattern between the first dielectric layer and the second dielectric layer.

3. The semiconductor chip of claim 2, further comprising:
a conductive bump on the second dielectric layer and connected to the redistribution pattern; and
a first external connection member connected to the conductive bump.

4. The semiconductor chip of claim 1, wherein the first and second dielectric layers each comprise a photo-imageable dielectric layer.

5. The semiconductor chip of claim 1, further comprising a connection via that penetrates the substrate and connects with the conductive pad.

6. The semiconductor chip of claim 1, wherein
the at least one residual test pattern is spaced apart in a first direction from the conductive pad, and
the first dielectric layer covers the pattern cut part by about 5 μm to about 10 μm in the first direction.

7. The semiconductor chip of claim 6, wherein the first dielectric layer covers the pattern cut part by about 10 μm to about 20 μm in a second direction that is transverse to the first direction.

8. The semiconductor chip of claim 1, wherein
the at least one residual test pattern comprises a plurality of residual test patterns, and wherein the plurality of residual test patterns are located along the edge region of the substrate, and
neither the first dielectric layer nor the second dielectric layer covers a space between the plurality of residual test patterns.

9. A semiconductor chip, comprising:
a substrate comprising a device region and an edge region;
a conductive pad on the device region of the substrate;
at least one residual test pattern on the edge region of the substrate;
a passivation layer on the substrate, the conductive pad, and the at least one residual test pattern;
a connection via that penetrates the substrate and connects with the conductive pad;
a redistribution layer on the passivation layer and including a first dielectric layer and a second dielectric layer;
a redistribution pattern between the first dielectric layer and the second dielectric layer;
a conductive bump on the second dielectric layer and connected to the redistribution pattern; and
a first external connection member connected to the conductive bump, wherein the at least one residual test pattern comprises:
a pattern cut part that has a lateral surface aligned with a lateral surface of the substrate; and
a pattern edge part between the pattern cut part and the conductive pad,
wherein the first dielectric layer entirely covers the pattern edge part and partially covers the pattern cut part, and
wherein there is a step difference between a sidewall of the first dielectric layer and a sidewall of the second dielectric layer such that the second dielectric layer does not cover the at least one residual test pattern.

10. The semiconductor chip of claim 9, wherein the first and second dielectric layers each comprise a photo-imageable dielectric layer.

11. The semiconductor chip of claim 9, wherein
the at least one residual test pattern is spaced apart in a first direction from the conductive pad, and
the first dielectric layer covers the pattern cut part by about 5 μm to about 10 μm in the first direction.

12. The semiconductor chip of claim 11, wherein the first dielectric layer covers the pattern cut part by about 10 μm to about 20 μm in a second direction that is transverse to the first direction.

13. The semiconductor chip of claim 9, wherein
the at least one residual test pattern comprises a plurality of residual test patterns, and wherein the plurality of residual test patterns are located along the edge region of the substrate, and
neither the first dielectric layer nor the second dielectric layer covers a space between the plurality of residual test patterns.

14. The semiconductor chip of claim 9, wherein
the sidewall of the second dielectric layer is inclined,
the pattern cut part comprises:
a first part covered with the first dielectric layer; and
a second part not covered with the first dielectric layer, and
the sidewall of the first dielectric layer is transverse to an edge of the first part.

15. The semiconductor chip of claim 9, wherein
the sidewall of the second dielectric layer is inclined,
the sidewall of the first dielectric layer is inclined and adjacent to the pattern cut part.

16. A semiconductor package, comprising:
a package substrate;
a semiconductor chip on the package substrate; and
a mold layer on the semiconductor chip and a top surface of the package substrate,
wherein the semiconductor chip comprises:
a chip substrate that comprises a device region and an edge region;
a conductive pad on the device region and below the chip substrate;
at least one residual test pattern on the edge region of the chip substrate and below the chip substrate;
a redistribution layer on a bottom surface of the chip substrate, the redistribution layer comprising a first dielectric layer and a second dielectric layer;
a redistribution pattern between the first dielectric layer and the second dielectric layer; and
a conductive bump below the second dielectric layer and connected to the redistribution pattern,
wherein the at least one residual test pattern comprises:
a pattern cut part that has a lateral surface aligned with a lateral surface of the chip substrate; and
a pattern edge part between the pattern cut part and the conductive pad,
wherein the first dielectric layer entirely covers the pattern edge part and partially covers the pattern cut part,
wherein the second dielectric layer does not cover the at least one residual test pattern, and
wherein there is a step difference between a sidewall of the first dielectric layer and a sidewall of the second dielectric layer.

17. The semiconductor package of claim 16, wherein
the package substrate comprises an upper conductive pad on the top surface of the package substrate, and
the semiconductor chip further comprises a first external connection member that connects the conductive bump to the upper conductive pad.

18. The semiconductor package of claim 16, wherein
the at least one residual test pattern is spaced apart in a first direction from the conductive pad, and
the first dielectric layer covers the pattern cut part by about 5 μm to about 10 μm in the first direction.

19. The semiconductor package of claim 18, wherein the first dielectric layer covers the pattern cut part by about 10 μm to about 20 μm in a second direction that is transverse to the first direction.

20. The semiconductor package of claim 16, wherein
the at least one residual test pattern comprises a plurality of residual test patterns, and wherein the plurality of residual test patterns are located along the edge region of the chip substrate, and
neither the first dielectric layer nor the second dielectric layer covers a space between the plurality of residual test patterns.
